(19) United States
(12) Patent Application Publication
(10) Pub. No.: US 2014/0043763 A1
(43) Pub. Date: Feb. 13, 2014

(54) PORTABLE ELECTRONIC DEVICE AND SYSTEM

(71) Applicant: ASUSTEK COMPUTER INC., Taipei (TW)

(72) Inventors: Chia-Ching NIU, Taipei (TW); Cheng-Yu WANG, Taipei (TW)

(73) Assignee: ASUSTEK COMPUTER INC., Taipei (TW)

(21) Appl. No.: 13/777,326

(22) Filed: Feb. 26, 2013

(30) Foreign Application Priority Data
Aug. 8, 2012 (TW) 101128648

(51) Int. Cl. H05K 7/20

(52) U.S. Cl. CPC H05K 7/20172
USPC 361/695

(57) ABSTRACT

A portable electronic system includes a portable device and a mobile device. The portable device includes a base, a bearing seat, and a connecting element. The base includes a fan and at least one first opening. The bearing seat includes at least one second opening. The connecting element connects the base and the bearing seat and includes a passage. The mobile device is detachably disposed at the bearing seat and includes at least one third opening. The base and the mobile device have corresponding passage and openings to bring heat airflow from inside of the mobile device to outside of the mobile device.

### CROSS-REFERENCE TO RELATED APPLICATION

This application claims the priority benefit of Taiwan application serial No. 101128648, filed on Aug. 8, 2012. The entirety of the above-mentioned patent application is hereby incorporated by reference herein and made a part of specification.

### BACKGROUND OF THE INVENTION

1. Field of the Invention

The disclosure relates to an electronic system and, more particularly, to a portable electronic system.

2. Description of the Related Art

An electronic device with a processing unit generates heat while operating. A fan is usually used in a notebook for dissipating heat. The portable device with small size is usually equipped with a processing unit including low efficiency. Therefore, the processing unit would not generate too much heat. With the high demand for the portable device and requirement of performance of the processing unit being higher and higher, the dissipating heat of the portable device becomes an important issue. Since the portable device is small sized, the fan for a general notebook cannot be disposed therein. Currently, the portable device is usually raised to help heat dissipation passively. However, the effect is poor.

### BRIEF SUMMARY OF THE INVENTION

A portable electronic system includes a portable device and a mobile device. The portable device includes a base, a bearing seat, and a connecting element. The base includes a fan and a first opening. The bearing seat includes a second opening. The connecting element is connected to the base and the bearing seat and includes a passage. The mobile device is detachably disposed at the bearing seat and includes a third opening.

In an embodiment of the disclosure, the base includes at least a fourth opening.

In an embodiment of the disclosure, the mobile device includes at least a fifth opening.

In an embodiment of the disclosure, airflow generated by the fan flows through the first opening, the passage, the second opening, and the third opening sequentially.

In an embodiment of the disclosure, airflow generated by rotation of the fan flows through the third opening, the second opening, the passage, and the first opening sequentially.

A portable device cooperates with a connecting element which can be detachably disposed at a mobile device. The portable device includes a base and a connecting element. The base includes a fan and a first opening which is adjacent the mobile device. The connecting element is disposed at the base.

In an embodiment of the disclosure, airflow generated by rotation of the fan flows to a side of the mobile device via the first opening.

In an embodiment of the disclosure, the connecting element includes a pivot.

In sum-, the portable electronic system in embodiment can actively bring heat airflow from inside of the mobile device to outside of the mobile device by the fan disposed at the base and a passage corresponding opening of the mobile device and the base. Furthermore, a first opening is directly formed at the base and adjacent formed at the mobile device to improve the heat dissipation from outside of the mobile device.

These and other features, aspects and advantages of the present disclosure will become better understood with regard to the following description, appended claims, and accompanying drawings.

### BRIEF DESCRIPTION OF THE DRAWINGS

FIG. 1A is a partial exploded diagram showing a portable electronic system according to a first embodiment of the disclosure;

FIG. 1B is a partial exploded diagram showing the portable electronic system in FIG. 1A;

FIG. 1C is a sectional diagram showing the portable electronic system in FIG. 1A;

FIG. 1D is another sectional diagram showing the portable electronic system in FIG. 1A;

FIG. 2A is a schematic diagram showing a portable electronic system according to a second embodiment of the disclosure;

FIG. 2B is a sectional diagram showing the portable electronic system in FIG. 2A;

FIG. 3A is a schematic diagram showing a portable electronic system according to a third embodiment of the disclosure; and

FIG. 3B is a sectional diagram showing the portable electronic system in FIG. 3A.

### DETAILED DESCRIPTION OF THE EMBODIMENTS

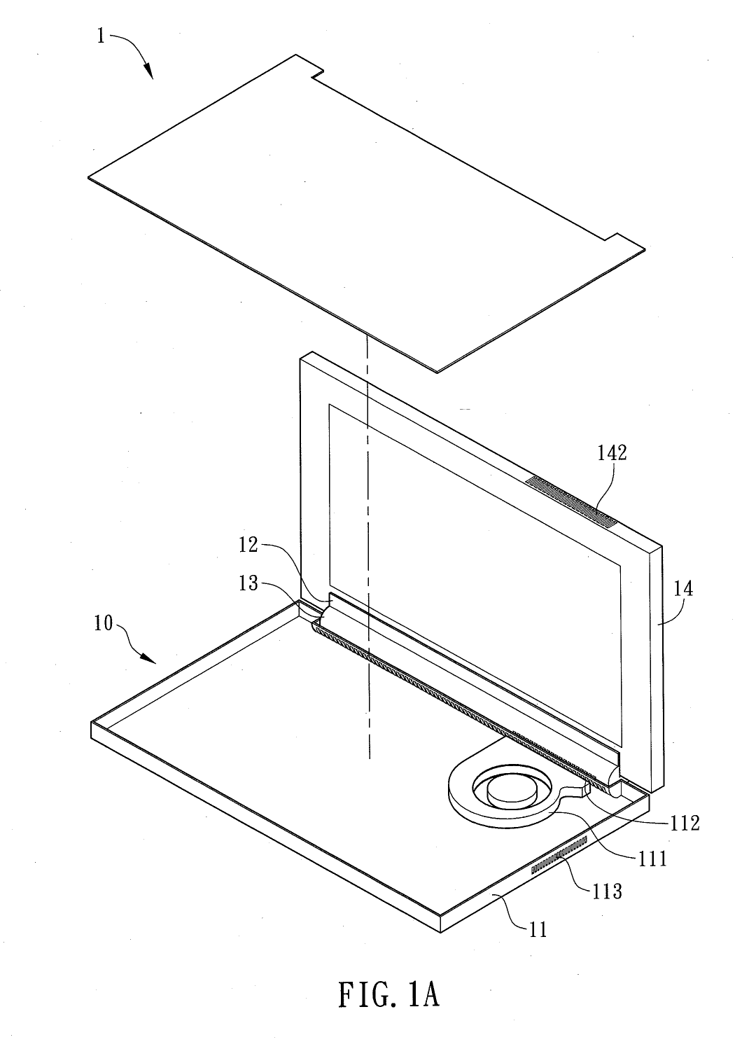

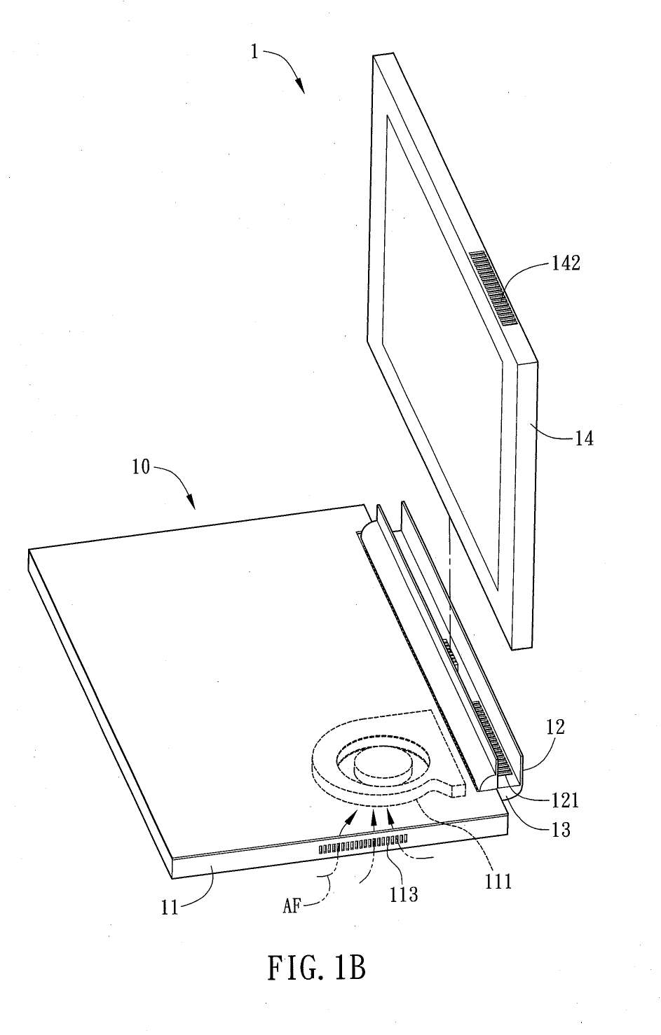

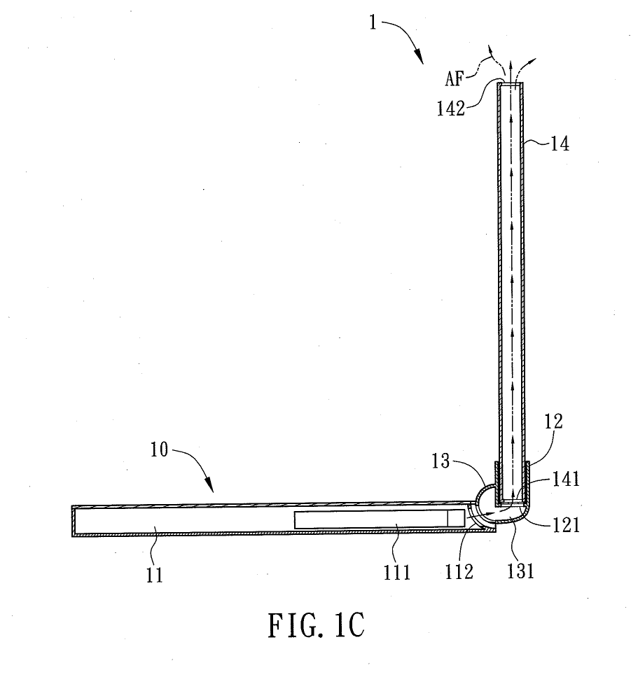

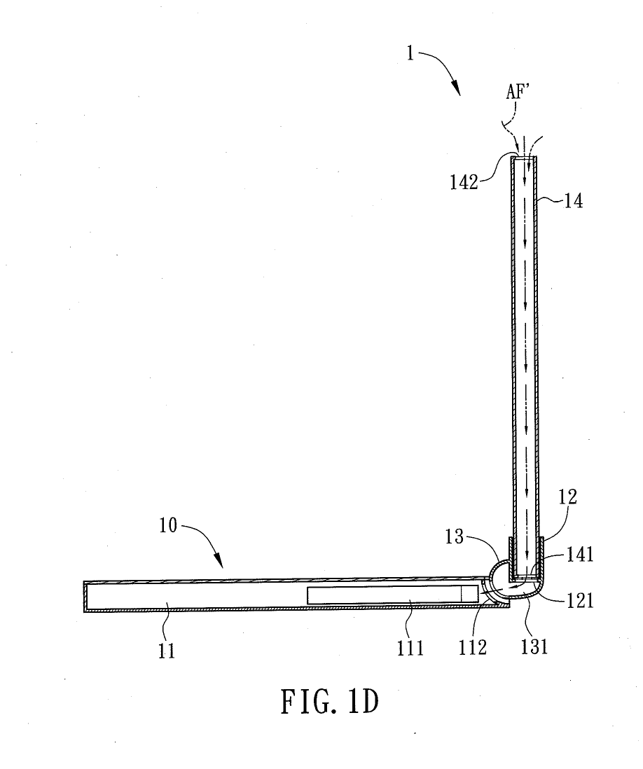

FIG. 1A is a partial exploded diagram showing a portable electronic system according to a first embodiment of the disclosure. A portable electronic system 1 includes a portable device 10 and a mobile device 14. The portable device 10 includes a base 11, a bearing seat 12, and a connecting element 13. The mobile device 14 is detachably connected with the portable device 10. In an embodiment of the disclosure, the base 11 includes a keyboard, which is not limited herein. Some structures in the drawing are omitted such as the keyboard for obtaining the clear drawing. FIG. 1B is a partial exploded diagram showing the portable electronic system in FIG. 1A, and FIG. 1C is a sectional diagram showing the portable electronic system in FIG. 1A.

In an embodiment of the disclosure, as shown in FIG. 1A to FIG. 1C, the base 11 includes a fan 111 and a first opening 112. The bearing seat 12 includes a second opening 121. The connecting element 13 is connected to the base 11 and the bearing seat 12. The connecting element 13 includes a passage 131. The mobile device 14 is detachably disposed at the bearing seat 12 and includes a third opening 141.

The base 11 also includes a fourth opening 113. When the fan 111 rotates, airflow AF is entered via the fourth opening 113. The entered airflow AF sequentially passes through the first opening 112, the passage 131 of the connecting element 13, the second opening 12 of the bearing seat 12, and the third opening 141 of the mobile device 14. The mobile device 14 further includes a fifth opening 142 for the airflow AF getting out from the mobile device 14.

In another embodiment, when the fan 111 rotates (as shown in FIG. 1D), the airflow AF' also can be sucked in via the fifth opening 142, and then sequentially passes through the third opening 141 of the mobile device 14, the second opening 121 of the bearing seat 12, the passage 131 of the connecting element 13, and the first opening 112 of the base 11, and then gets out from the fourth opening 113 along with the heat of the mobile device 14.

The mobile device 14 of the portable electronic system 1 and the bearing seat 12 can be connected by fastening, locking, magnet attaching, which is not limited herein.

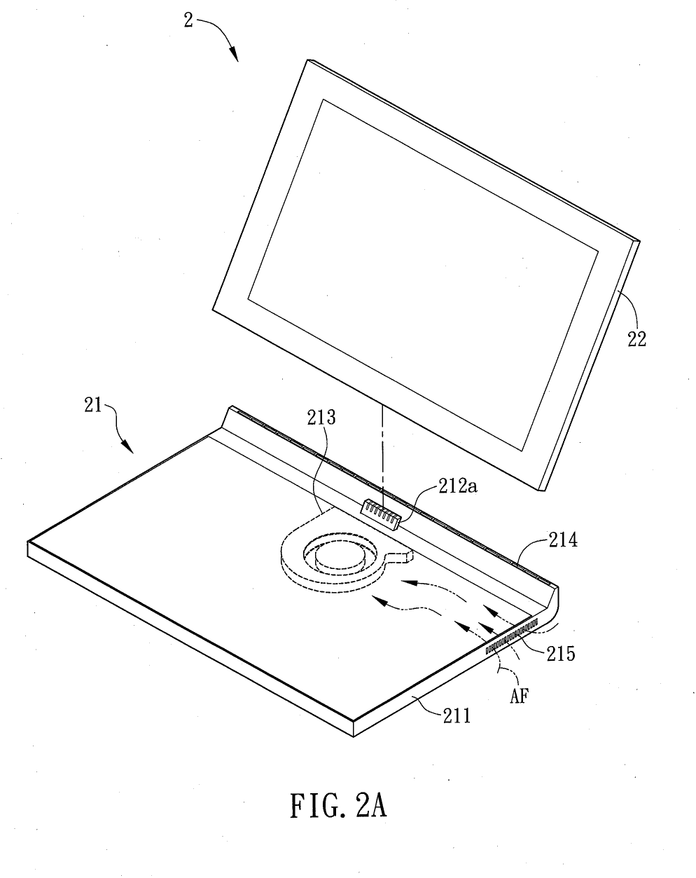

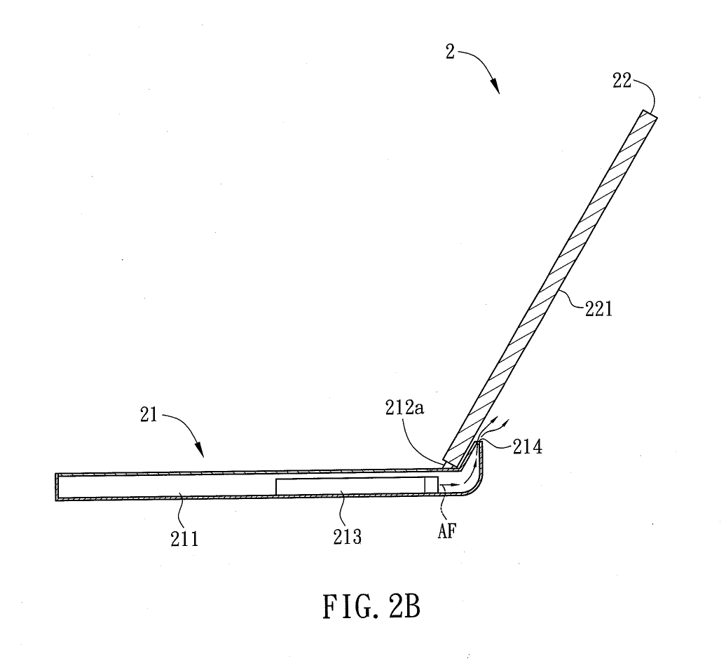

FIG. 2A is a schematic diagram showing a portable electronic system according to a second embodiment of the disclosure. The portable electronic system 2 includes a portable device 21 and a mobile device 22. The portable device 21 includes the base 211 and the connecting element 212a. FIG. 2B is a sectional diagram showing the portable electronic system in FIG. 2A.

As shown in FIG. 2A and FIG. 2B, the base 211 includes a fan 213 and a first opening 214. The connecting element 212a is disposed at the base 211. The mobile device 22 is detachably disposed at the connecting element 212a. In an embodiment of the disclosure, the first opening 214 is adjacent formed at the mobile device 22.

The base 211 includes a fourth opening 215. When the fan 213 rotates, the airflow AF is sucked in via a fourth opening 215 and flows to a side of the mobile device 22 such as a rear panel 221 via the first opening 214. The connecting element 212a may be a protruding structure, a recess, or a magnet member to support the mobile device 22. The type of the connecting element 212a is not limited herein.

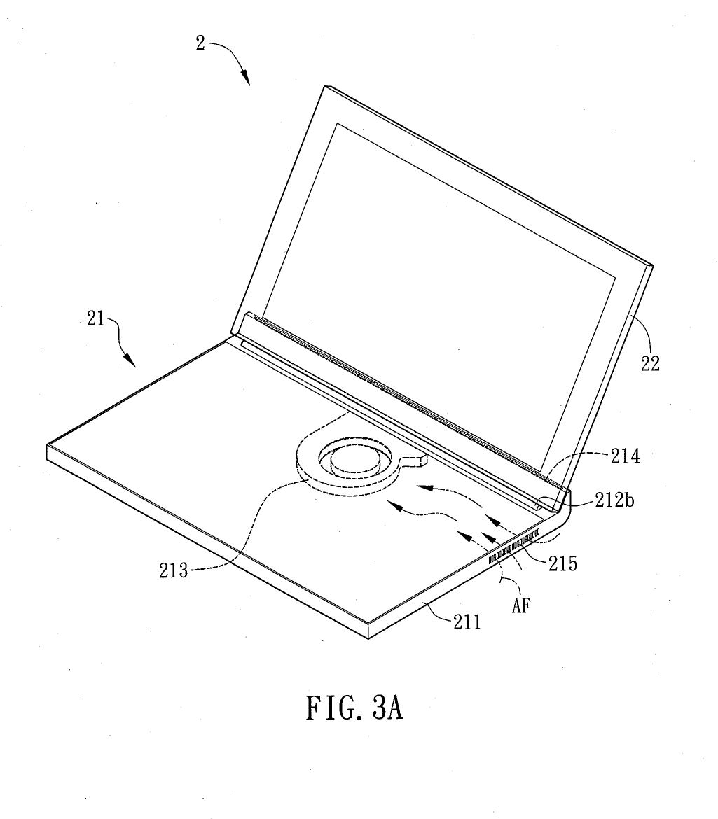

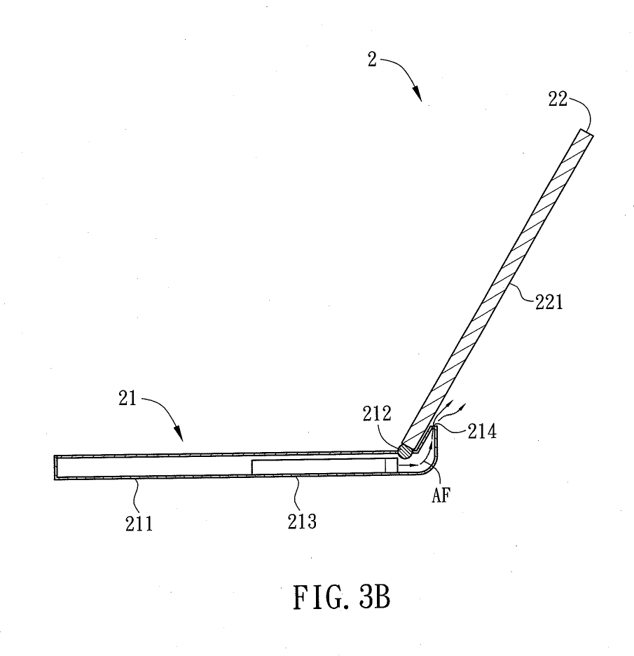

Additionally, the connecting element also may include a pivot as shown in FIG. 3A and FIG. 3B. A portable electronic system 2 includes a portable device 21 and a mobile device 22. The portable device 21 includes the base 211 and the connecting element 212b. The connecting element 212b may a rotating pivot. The connecting mode between the mobile device 22 and the connecting element 212b is not limited herein as long as they are detachable and can rotate simultaneously. For example, two semi-circular structures are disposed at the mobile device 22 to allow them to be fastened to the connecting element 212b and rotate with the mobile device. The connecting element 212b also may be a magnet member, and the corresponding part of the mobile device 22 is metal or magnet.

Although the present disclosure has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. A portable electronic device, comprising:
a base including a fan and at least one first opening;
a bearing seat including at least one second opening; and
a connecting element connecting the base and the bearing seat and including a passage.

2. The portable electronic device according to claim 2, wherein the base includes at least one fourth opening.

3. A portable electronic device cooperating with a connecting element detachably disposed at a mobile device, comprising:
a base including a fan and at least one first opening, wherein the first opening is adjacent the mobile device; and
a connecting element disposed at the base.

4. The portable electronic device according to claim 3, wherein airflow generated by the fan flows to a side of the mobile device via the first opening.

5. The portable electronic device according to claim 3, wherein the connecting element includes a pivot.

6. A portable electronic system, comprising:
a base including a fan and at least one first opening ;
a bearing seat including at least one second opening; and
a connecting element connecting the base and the bearing seat and including a passage; and
a mobile device detachably disposed at the bearing seat and including at least one third opening.

7. The portable electronic system according to claim 6, wherein the base includes at least one fourth opening.

8. The portable electronic system according to claim 6, wherein the mobile device includes at least one fifth opening.

9. The portable electronic system according to claim 6, wherein airflow generated by the fan flows via the first opening, the passage, the second opening, and the third opening sequentially.

10. The portable electronic system according to claim 6, wherein airflow generated by rotation of the fan flows via the third opening, the second opening, the passage, and the first opening sequentially.
